(19) United States
(12) Patent Application Publication
(10) Pub. No.: US 2026/0074622 A1
(43) Pub. Date: Mar. 12, 2026

(54) MULTI-LEVEL SWITCHING POWER CONVERTER SYSTEMS

(71) Applicant: MISSION POWER CORP., Potsdam, NY (US)

(72) Inventors: MATTHEW HONICKMAN, Potsdam, NY (US); RUSSEL MARVIN, Potsdam, NY (US); DAVID LEACH, Torrington, CT (US)

(21) Appl. No.: 18/828,272

(22) Filed: Sep. 9, 2024

Related U.S. Application Data
(63) Continuation of application No. 18/828,198, filed on Sep. 9, 2024.

(51) Int. Cl. H02M 3/335; H02M 7/00; H02M 7/483; H03K 17/687; H05K 1/18

(52) U.S. Cl. CPC H02M 3/33507; H02M 7/003; H02M 7/4837; H03K 17/687; H05K 1/181

(57) ABSTRACT

One example includes a TAB switching converter that includes a transformer, a first switching stage, a second switching, and a third switching stage to convert between a DC voltage and an AC voltage. Switching nodes of the second and third switching stages can be directly coupled to respective first and second windings of the transformer. The system further includes a switch controller configured to generate switching signals at a variable frequency that varies as a function of a power metric associated with a frequency of the AC voltage, and to provide a variable phase shift between the respective switching signals that control one switch in each of pairs of switches in at least one of the second and third switching stages relative to another one switch in each of the pairs of the respective at least one of the second and third switching stages.

### RELATED APPLICATIONS

This application claims priority from U.S. patent application Ser. No. 18/828,198, filed 9 Sep. 2024, which is incorporated herein in its entirety.

### TECHNICAL FIELD

The present description relates generally to electronic circuits, and specifically to multi-level switching power converter systems.

### BACKGROUND

Power converter circuits are implemented in a variety of applications to convert a voltage from one type (DC or AC) and/or amplitude to another type and/or amplitude. One example of power converter circuits are switching power converters that implement switches to control the flow of current from an input, such as through circuit devices (e.g., transformers and/or capacitors), to generate a voltage at an output. Additionally, some power converters can be multi-level converters designed to provide more than one voltage amplitude. Some power converter circuits may be required to operate at very high voltage or current amplitudes. Such high-power applications can present challenges that are not present in smaller power converter circuits, such as implemented in handheld computing devices. Such challenges can include ripple currents through transformers, high voltage amplitude differentials across switches, saturation of magnetic circuit devices, and other potential problems.

### SUMMARY

In one example, a multi-level switching power converter system includes a multi-level switching converter arranged as a tri-active bridge (TAB) module. The TAB module includes a transformer having a first winding and a second winding. A first switching stage includes a first set of switches arranged as a first H-bridge and controlled by a first set of switching signals to convert between an AC voltage and a first DC voltage. The TAB module also includes a second switching stage having a second set of switches arranged as a second H-bridge and controlled by a second set of switching signals. The second switching stage includes a first switching node between a first pair of the second set of switches and a second switching node between a second pair of the second set of switches. The first and second switching nodes can be directly coupled to the first winding to one of provide or receive a first voltage associated with the first winding in response to one of the first DC voltage and a second DC voltage. The TAB module further includes a third switching stage having a third set of switches arranged as a third H-bridge and controlled by a third set of switching signals. The third switching stage includes a third switching node between a first pair of the third set of switches and a fourth switching node between a second pair of the third set of switches. The third and fourth switching nodes can be directly coupled to the second winding to one of provide or receive a second voltage associated with the second winding in response to the other of the first and second DC voltages. The system further includes a switch controller configured to generate the first, second, and third sets of switching signals, to provide at least one of the first, second, and third sets of switching signals at a variable frequency that varies as a function of a power metric associated with a frequency of the AC voltage, and to provide a variable phase shift between the respective switching signals that control one switch in each of the first and second pairs of at least one of the second and third sets of switches relative to another one switch in each of the first and second pairs of the respective at least one of the second and third sets of switches.

In another example, a transformer assembly includes a transformer comprising a primary winding, a secondary winding, and a magnetic core formed from a first material. The transformer assembly also includes a magnetic element coupled to the magnetic core and formed from a second material different from the first material of the magnetic core. The magnetic element can be configured to divert a portion of magnetic flux from the magnetic core of the transformer. The transformer assembly further includes a sense coil magnetically coupled to the magnetic element and configured to provide a feedback signal that is indicative of saturation of the magnetic core of the transformer.

### BRIEF DESCRIPTION OF THE DRAWINGS

FIG. 1 illustrates an example block diagram of a multi-level switching power converter system.

FIG. 2 illustrates an example block diagram of a switching converter.

FIG. 3 illustrates an example circuit diagram of a switching converter.

FIG. 4 illustrates another example circuit diagram of a switching converter.

FIG. 5 illustrates an example diagram of different states of a switching converter.

FIG. 6 illustrates another example block diagram of a switching converter.

FIG. 7 illustrates another example block diagram of a multi-level switching power converter system.

FIG. 8 illustrates another example circuit diagram of a switching converter.

FIG. 9 illustrates example timing diagrams.

FIG. 10 illustrates another example of different states of a switching converter.

FIG. 11 illustrates an example diagram of a transformer.

FIG. 12 illustrates another example diagram of a transformer.

FIG. 13 illustrates an example circuit diagram of a multi-level switching power converter system.

### DETAILED DESCRIPTION

The present description relates generally to electronic circuits, and specifically to multi-level switching power converter systems. As described herein, the term “multi-level switching power converter system” can refer to any of a variety of power converters that can generate multiple amplitudes of output voltages, such as variably or concurrently, that can be aggregated or provided separately. Examples of multi-level switching power converter systems described herein can include flying capacitor switching converters and tri-active bridge (TAB) switching converters. As an example, the flying capacitor switching converters and TAB switching converters described herein can be implemented in multi-level switching power converter systems that operate in high power applications, such as at voltages greater than 500 volts, and up to thousands of volts (e.g., 2 kV).

A multi-level switching power converter system described herein can include a plurality of switching converters, with each switching converter including a plurality of switching stages, each including one or more switches. The multi-level switching power converter system can include a switch controller configured to generate switching signals that are provided to the switches of the switching stages. As an example, the switch controller can provide the switching signals at a variable frequency, such as to control the activation frequency of the switches of one or more of the switching stages. As an example, the frequency of the activation of the switches can be adjusted to adjust the magnetizing current of a transformer, to provide better efficiency by mitigating switching losses, to mitigate saturation of the transformer core, and/or to provide to provide better efficiency at lower current amplitudes. As an example, the frequency of the switching signals can be varied as a function of a power metric, and can be within a fundamental period of an AC waveform associated with the power converter circuit (e.g., an AC input voltage).

As another example, the DAB switching converter or TAB switching converter can correspond to one of a set of DAB switching converters or TAB switching converters to provide an output voltage in response to an input voltage. The DAB switching converters or TAB switching converters can be arranged in combinations of parallel and series with respect to the inputs and outputs to provide different combinations of step-up and step-down voltage conversion. A TAB switching converter can include a first switching stage that converts between an AC voltage (e.g., an AC input voltage) and a DC voltage. A DC voltage is provided by a second switching stage to a primary winding of a transformer (e.g., a planar transformer) to generate an output current via a secondary winding of the transformer. The output current is provided through a third switching stage to generate a second DC voltage.

The DAB switching converter can be arranged similar to the TAB switching converter, but without the first switching stage. Because the DAB switching converter and TAB switching converter can operate at very high voltages (e.g., with 2 kV isolation between the primary and secondary), resonant inductors and/or blocking capacitors would be required to be impractically large and expensive. Therefore, the switch controller can vary the phase and/or frequency of one or more of the switching stages to control the peak current, magnetizing current, and reactive power of the transformer independently of the power flow to mitigate saturation of the magnetic core of the transformer. Such control of the switching stages can thus obviate the need for a resonant inductor and/or a blocking capacitor in high power implementations.

In addition, the transformer of the DAB switching converter or TAB switching converter can include a magnetic element that is configured to detect and mitigate potential saturation of the magnetic core of the transformer. The magnetic element can be coupled to the magnetic core to divert a portion of the magnetic flux from the magnetic core through the magnetic element. The portion of the magnetic flux can thus be measured by a sensing coil that passively senses the magnetic flux through the magnetic element based on an inductively generated current in the sense coil that acts as a feedback signal.

As an example, the magnetic element can be formed from a material that has a higher magnetic permeability than the magnetic core, and can thus saturate before the magnetic core. As a result, based on the feedback signal, the switch controller can predict saturation of the magnetic core of the transformer, and can thus adjust the switching signals (e.g., phase and/or frequency) accordingly to mitigate saturation of the magnetic core.

As another example, a multi-level switching power converter system can include multiple flying capacitor switching converters (e.g., in a three-phase arrangement). A given flying capacitor switching converter can provide multiple voltage levels between the switching stages based on a quantity of the switching stages between the input, the output, and each set of flying capacitors. The switching stages can each include an opposing pair of switches that are coupled to opposing nodes at the terminals of the flying capacitors.

As an example, the flying capacitor switching converter can also include an output filter that includes at least one saturable inductor to mitigate current ripple at the switching frequency of the switches in the switching stages, such as to mitigate electro-magnetic interference (EMI) in high power applications. As described herein, the switch controller can control the switches of the switching stages of the flying capacitor switching converter to selectively adjust a quantity of the voltage levels between the nominal quantity and an adjusted quantity less than the nominal quantity.

For example, the switch controller can concurrently activate the opposing pair of switches in a given switching stage to short a flying capacitor to the input or the output, or to short two flying capacitors together. As an example, the switch controller can provide a voltage balancing algorithm to set a voltage difference across the switches to approximately zero. The switch controller can thus monitor feedback associated with the flying capacitor switching converter to determine an appropriate time to most efficiently activate the switches to adjust the voltage levels.

For example, the switch controller can determine when a voltage amplitude across a set of switches are approximately equal. In response to the equal voltage across the switches, the switch controller can implement the concurrent activation of the switches to reduce the quantity of voltage levels of the flying capacitor switching converter and to redistribute the voltage amplitudes of the voltage levels based on the adjusted quantity of voltage levels. As described herein, with respect to a switch, the term “activate” describes closing the switch to provide a short circuit to allow current to pass through the switch. The term “deactivate” describes opening the switch to provide an open circuit to cease or prevent current flow.

In addition, the switch controller can monitor feedback associated with the flying capacitor switching converter to determine an appropriate time to most efficiently activate the switches to adjust the voltage levels. For example, the switch controller can determine when a voltage amplitude across the pair of flying capacitors, or between the flying capacitor and the input or output, are approximately equal. Thus, the switching controller can activate the switches with minimal voltage drop across the switches to minimize switching losses.

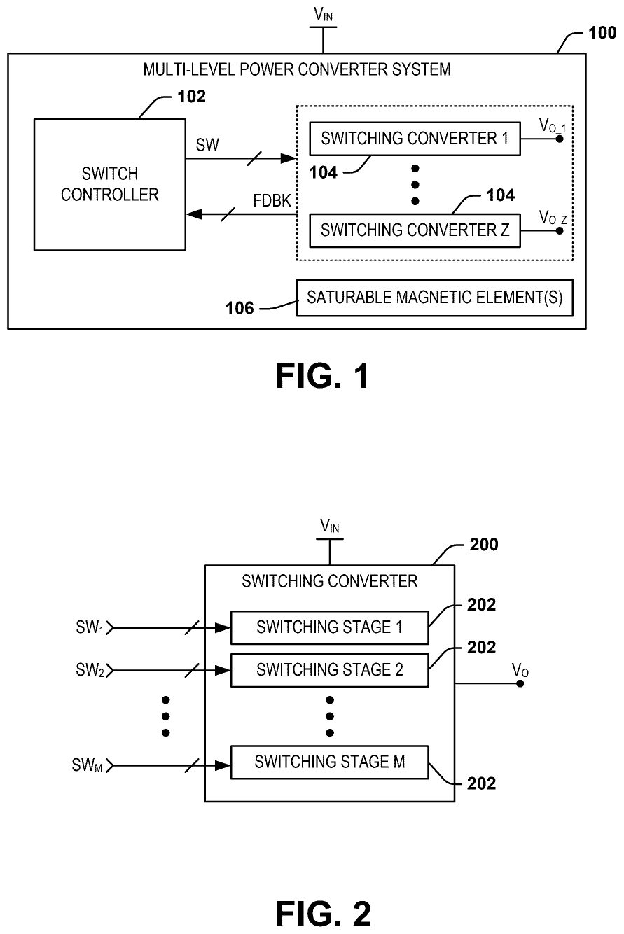

FIG. 1 illustrates an example block diagram of a multi-level switching power converter system 100. The multi-level switching power converter system 100 can be implemented in any of a variety of power-providing applications, such as for high power applications. For example, the multi-level switching power converter system 100 can be implemented for motor controls, electric vehicle charging, or a variety of other applications.

The multi-level switching power converter system 100 includes a switch controller 102 and a plurality Z of switching converters 104, where Z is greater than one. Each of the switching converters 104 is configured to generate a voltage, demonstrated as voltage V_{O_1} through V_{O_Z}, based on an input voltage V_{IN}. Each of the switching converters 104 includes at least one switch that is controlled by a set of switching signals, demonstrated in the aggregate by a signal SW, that are provided by the switch controller 102. As an example, the switching converters 104 can be implemented as a set of flying capacitor switching converters or TAB switching converters.

As described herein, the switch controller 102 can provide the switching signals SW at a variable frequency and/or phase relative to each other to provide activation of the switches at variable frequencies. As an example, the switches can be fabricated as semiconductor devices (e.g., silicon carbide or gallium nitride transistors). The variable frequency and/or phase of the switching converter 104 switch activation can thus provide for efficient control of the switching converters 104 of the multi-level switching power converter system 100, thereby reducing switching losses and minimizing the size of filters in the multi-level switching power converter system 100.

FIG. 2 illustrates an example block diagram of a switching converter 200. The switching converter 200 can correspond to one of the switching converters 104 in the example of FIG. 1. Therefore, the switching converter 200 can be one of a flying capacitor switching converter, a TAB switching converter, or a set of cascaded H-bridges. The switching converter 200 includes a plurality N of switching stages 202, where N is greater than one, that each include a set of switches (e.g., high-frequency switching transistor devices). Each of the switching stages 202 is demonstrated as controlled by a respective set of switching signals SW₁ through SW_{N} that are provided from the switch controller 102 (e.g., at a variable frequency and/or phase).

As an example, the switching converter 200 can be arranged as a flying capacitor switching converter. In a flying capacitor switching converter configuration, each of the switching stages 202 can be arranged as a pair of switches arranged on opposite terminals of one or two flying capacitors. The switching stages 202 can thus be controlled by the switching signals SW₁ through SW_{N} to provide the respective output voltage V_{O} and a plurality of voltage levels across each of the flying capacitors.

As described in greater detail herein, the switching stages 202 can also be controlled by the switching signals SW₁ through SW_{N} such that both switches of a given switching stage 202 are activated to provide a short-circuit of both terminals of a flying capacitor to another flying capacitor, or to an input on which the input voltage V_{IN} is provided, or to an output from which the output voltage V_{O} is provided. In this manner, the switch controller 102 can selectively change a quantity of the voltage levels between a nominal quantity and a quantity that is less than the nominal quantity, thereby redistributing the input voltage V_{IN} across the remaining voltage levels. Additionally, the switch controller 102 can vary the frequency of the sets of switching signals SW₁ through SW_{N} to a fundamental period of the AC voltage (e.g., 50 Hz or 60 Hz for power line AC applications). For example, the frequency can be decreased at lower currents.

As another example, the switching converter 200 can be arranged as a TAB switching converter. As an example, the TAB switching converter 200 can be arranged in a module that includes a planar transformer arranged on printed circuit boards (PCBs). For a TAB switching converter 200, each of the switching stages 202 can be arranged as a set of switches arranged as an H-bridge. The switching stages 202 can thus be controlled by respective sets of switching signals SW₁ and SW₂ to provide the input voltage V_{IN} (e.g., a DC voltage) to the primary winding of the transformer via the first switching stage 202 to generate the output voltage V_{O} (e.g., a DC voltage) from the secondary winding of the transformer via the second switching stage 202.

A TAB switching converter 200 can convert between AC and DC voltages. For example, the TAB switching converter 200 can convert an AC input voltage V_{IN} to a DC output voltage V_{O}, or can convert a DC input voltage V_{IN} to an AC output voltage V_{O} based on the respective sets of switching signals SW₁, SW₂, and SW₃. Similar to as described above, the switch controller 102 can vary the frequency of the sets of switching signals SW₁, SW₂, and SW₃ to within a fundamental period of the AC voltage (e.g., 50 Hz or 60 Hz for power line AC applications).

For a TAB switching converter, the switch controller 102 can adjust the phase of the switching signals SW₁ through SW₃ relative to each other. For example, the switch controller 102 can implement a dual phase-shift scheme. The dual phase-shift scheme includes phase-shifting one of the sets of switching signals SW₁ through SW₃ relative to another of the sets of switching signals associated respectively with the switching stages 202 that are coupled to the first and second windings of the transformer. The dual phase-shift scheme can also include phase-shifting pairs of switching signals SW₁ through SW₃ in a given set of switching signals associated with one of the switching stages 202 relative to each other. In this manner, the resonance of the transformer can be controlled in an active manner, thus obviating the need for a bulky resonant reactive circuit device in series with the windings of the respective transformer.

The discussion of the different types of switching converters 200 describes generating an output voltage V_{O} in response to an input voltage V_{IN}. However, the switching converters described herein (e.g., flying capacitor switching converters and/or cascaded TAB switching converters) may not be limited to unidirectional operation, but can instead be implemented bidirectionally.

Referring back to the example of FIG. 1, the multi-level switching power converter system 100 includes at least one saturable magnetic element 106. The saturable magnetic element(s) 106 can be arranged as a variety of different types of magnetic elements for different purposes in the multi-level switching power converter system 100. As an example, the saturable magnetic element(s) 106 can correspond to one or more inductors in an output filter of one or more of the switching converters 104 (e.g., arranged as flying capacitor switching converters).

As another example, the saturable magnetic element(s) 106 can correspond to one or more inductors in series with all or a proper subset of an AC rectifier switching stage (e.g., to rectify an AC input voltage V_{IN}) of the switching converters 104 (e.g., arranged as TAB switching converters). As another example, the saturable magnetic element(s) 106 can correspond to a saturable magnetic flux sensor associated with a transformer of one or more of the switching converters 104 arranged as TAB switching converters, as described in greater detail herein.

In the example of FIG. 1, the switch controller 102 can control the activation of the switches in the switching converters 104 and/or can vary the frequency and/or phase of the switching signals SW in response to one or more feedback signals FDBK. As one example described in greater detail herein, the feedback signal(s) FDBK can be associated with voltages across flying capacitors, such that the switch controller 102 can activate the switch(es) of the switching converter(s) 104 in response to an approximately zero volt differential across the switch(es), such as to change a quantity of voltage levels provided by a respective flying capacitor switching converter. Thus, the switch controller 102 can mitigate large current spikes between flying capacitors when decreasing the quantity of voltage levels in response to the feedback signal(s) FDBK to mitigate damage to the flying capacitor converter.

As another example described in greater detail herein, the feedback signal(s) FDBK can be provided from a magnetic flux sensor that senses magnetic flux of a transformer of one or more of the switching converters 104 arranged as TAB switching converters. For example, the feedback signal(s) FDBK can be provided from a sense coil associated with a saturable magnetic element 106 arranged to divert a portion of flux from the magnetic core of the respective transformer. The magnetic flux through the saturable magnetic element 106 can thus be indicative of the magnetic flux through the magnetic core of the transformer, and can thus be predictive of saturation of the magnetic core.

Accordingly, the switch controller 102 can control the frequency and/or phase of the switches in one of the switching stages of the respective TAB switching converter, and/or can control the phase of a set of switches relative to another set of switches of an H-bridge switching stage of the respective TAB switching converter. As a result, the switch controller 102 can mitigate saturation of the magnetic core of the transformer without including excessively large resonant active circuit devices (e.g., resonant inductors and/or blocking capacitors) in series with the windings of the respective transformer.

Examples of multi-level switching power converter systems 100 having the different types of switching converters 104, as well as the manner of controlling the switches therein, is described in greater detail herein.

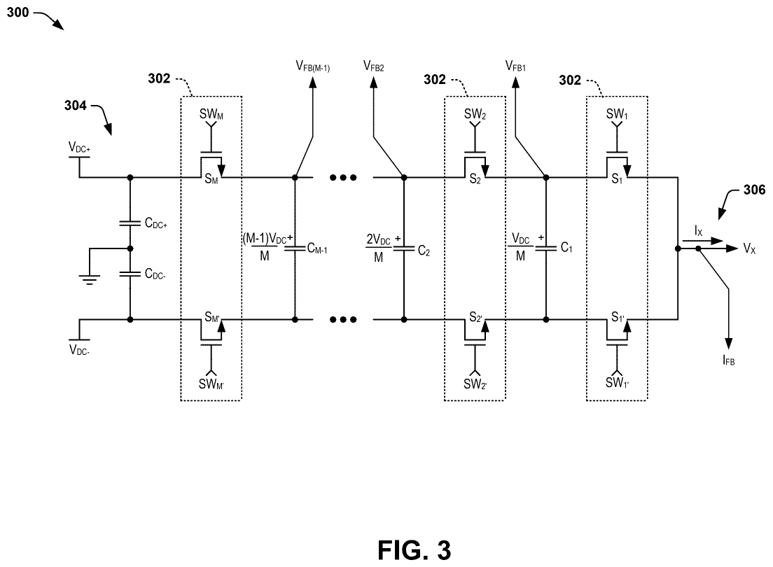

FIG. 3 illustrates an example circuit diagram of a switching converter 300. The switching converter 300 is demonstrated in the example of FIG. 3 as a flying capacitor switching converter, and can correspond to one of the switching converters 104 in the example of FIG. 1 or the switching converter 200 in the example of FIG. 2. Therefore, reference is to be made to the examples of FIGS. 1 and 2 in the following example of FIG. 3.

The flying capacitor switching converter 300 includes a cascaded arrangement of complementary switching stages 302, each demonstrated as including a switch and a complementary switch. The example of FIG. 3, the flying capacitor switching converter 300 is demonstrated as including a quantity M of switching stages between an input 304 and an output 306, where M is greater than one. Therefore, the switches are labeled S₁ through S_{M} and the complementary switches are labeled as S₁′ through S_{M}′. The switches S₁ through S_{M} are arranged between the output 306 and a positive rail input voltage V_{DC+} at the input 304. The switches S₁′ through S_{M}′ are arranged between the output 306 and a negative rail input voltage V_{DC-} at the input 304. A DC bus voltage V_{DC} is defined as a difference between the rail voltages V_{DC+} and V_{DC-}.

The switch S_{M} in the M^{th} switching stage 302 of the complementary switching stages 302 is coupled to the positive rail voltage V_{DC+} and is separated from a bus mid-point via a capacitor C_{DC+}. The switch S_{M}′ in the M^{th} switching stage 302 is coupled to the negative rail voltage V_{DC-} and is separated from the bus mid-point via a capacitor C_{DC-}. The bus voltage V_{DC} can be provided as a high voltage (e.g., at least 500 volts) for any of a variety of high power applications (e.g., motor control). Additionally, the terms “input” and “output” are provided herein by example, such that the flying capacitor switching converter 300 can operate bidirectionally.

The switches S₁ through S_{M} are controlled via respective switching signals SW₁ through SW_{M} (collectively “SW”), while the complementary switches S₁′ through S_{M}′ are controlled via respective switching signals SW₁′ through SW_{M}′ (collectively “SW′”), respectively. The switches S₁ through S_{M} and the complementary switches S₁′ through S_{M}′ can each be fabricated as identical transistors devices, such as gallium nitride (GaN) switches or silicon carbide (SiC) to achieve high speed switching via the switching signals SW and SW′.

The switching signals SW and SW′ can be provided from the switch controller 102 and can be provided at a variable frequency, as described herein. In addition, as also described herein, a given complementary pair of the switching signals SW and SW′ can be provided by the switch controller 102 to concurrently activate a given one of the switches S₁ through S_{M} and the complementary one of the switches S₁′ through S_{M}′.

The flying capacitor switching converter 300 also includes a plurality M-1 of flying capacitors that interconnect nodes between the complementary switching stages 302. In the example of FIG. 3, the flying capacitors are demonstrated as C₁ through C_{M-1}. Thus, the flying capacitors C₁ through C_{M-1} are likewise arranged in a cascaded sequence to provide a plurality of voltage levels between the input voltage V_{DC}. An amplitude of a given voltage level across a respective one of the flying capacitors C₁ through C_{M-1} is nominally controlled to have a value of J*V_{DC}/M, where J is an index of a given one of the flying capacitors C₁ through C_{M-1}.

For an example of a 400 volt DC bus and M=4, the nominal voltage across the flying capacitor C₁ is 100 V, the nominal voltage across flying capacitor C₂ is 200 V, etc. The nominal voltage across any of the complementary switching stages 302 is thus the voltage across two neighboring flying capacitors (e.g., 100 V in the previous example). The number M of stages can thus correspond to a desired quantization of the output voltage V_{X}, with N discrete voltage levels available, where N is a quantity of voltage levels (N=M+1). The N voltage levels thus include the V_{DC+}, the voltage V_{DC-}, and M−1 evenly spaced voltage levels therebetween. The output voltage V_{X} is provided to a specific amplitude of the N voltage levels based on the selective complementary activation of the complementary switching stages 302 via the switching signals SW and SW′.

In the example of FIG. 3, the flying capacitor switching converter 300 is demonstrated as providing an output current I_{X} from the output 306, with the output current I_{X} corresponding to the current flowing through the flying capacitor switching converter 300. The current I_{X} can be provided from the output 306 to a load (e.g., a motor), with the selective activation of the switches of the complementary switching stages 302 defining an amplitude of the associated output voltage V_{X} relative to V_{DC}.

In addition, the flying capacitor switching converter 300 is demonstrated in the example of FIG. 3 as providing a plurality of feedback signals, such as to the switch controller 102. The feedback signals can include a feedback current I_{FB} that is proportional to the output current I_{X}, and can include feedback voltages V_{FB} from each of the flying capacitors C₁ through C_{M-1}, such that each of the feedback voltages V_{FB} correspond to respective voltage levels of the flying capacitor switching converter 300. The feedback voltages V_{FB} can be monitored in any of a variety of ways, such as by directly monitoring the amplitude of the voltages of the flying capacitors C₁ through C_{M-1}, or based on monitoring the switch states and the output voltage V_{X}−V_{DC}.

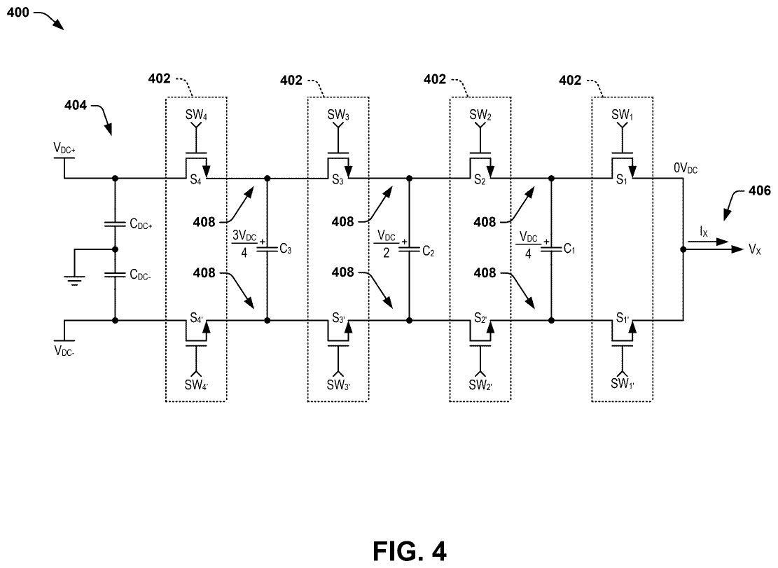

FIG. 4 illustrates another example circuit diagram of a flying capacitor switching converter 400 demonstrated as an example of the flying capacitor switching converter 300 having four switching stages 402. Therefore, the flying capacitor switching converter 400 includes four switches S₁ through S₄ that are controlled by switching signals SW₁ through SW₄, respectively, and includes four complementary switches S₁′ through S₄′ that are controlled by switching signals SW₁′ through SW₄′, respectively.

The nominal amplitudes of the voltage levels are therefore demonstrated as V_{DC} at an input 404, zero (demonstrated as “0V_{DC}”) at an output 406, and multiples of V_{DC}/4 across each of three respective flying capacitors C₁ through C₃, and thus 3V_{DC}/4, V_{DC}/2, and V_{DC}/4 each at respective nodes 408. Accordingly, the flying capacitor switching converter 400 includes a nominal quantity of voltage levels of five (V_{DC}, 3V_{DC}/4, V_{DC}/2, V_{DC}/4, and 0V_{DC}) relative to the voltage V_{DC}. The feedback signals FDBK are not demonstrated in the example of FIG. 4 for brevity, but can also be included in the flying capacitor switching converter 400.

During a normal operating mode, the switch controller 102 can provide the switching signals SW and SW′ to the flying capacitor switching converter 400 at a switching frequency such that one of each of the complementary pairs of switches S₁ through S₄ and S₁′ through S₄′, respectively, are activated at a given time to provide the voltage V_{X}. However, as described above, a given complementary pair of the switching signals SW and SW′ can be provided by the switch controller 102 to concurrently activate a given one of the switches S₁ through S₄ and the complementary one of the switches S₁′ through S₄′ in a different operating mode that includes fewer voltage levels.

By concurrently activating both switches of a given one of the switching stages 402, the switch controller 102 can provide a short circuit between the nodes 408 of a given one of the flying capacitors C₁ through C₃ and another node on which a different voltage level is nominally provided. The short circuit can thus be between the input 404 and nodes 408 of flying capacitor C₃, between the output 406 and nodes 408 of flying capacitor C₁, or between nodes 408 of any sequential two of the flying capacitors C₁ through C₃.

Consequently, the switch controller 102 can concurrently activate both switches of a given one of the switching stages 402 to decrease the quantity of the voltage levels of the flying capacitor switching converter 400 from the nominal quantity in a normal operating mode to another quantity that is less than the nominal quantity in a different operating mode. The switch controller 102 can also deactivate one of the switches of the respective switching stages 402 to increase the quantity of the voltage levels of the flying capacitor switching converter 400 back to the nominal quantity, and thus back to the normal operating mode at which one of each of the complementary switch pairs is activated at the switching frequency. Accordingly, the switch controller 102 can selectively change the quantity of the voltage levels between the nominal quantity and lesser quantities, and thus operating modes of the flying capacitor switching converter 400. In response to a change in quantity of voltage levels, the flying capacitor switching converter 400 can reallocate the nominal amplitudes of the voltage levels approximately equally between the input voltage V_{DC} and zero.

By selectively adjusting the quantity of voltage levels of the flying capacitor switching converter 400, the flying capacitor switching converter 400 can be operated more efficiently in a different operating mode. For example, the input voltage V_{DC} of the flying capacitor switching converter 400 can change depending on power-providing application and/or operating mode of the multi-level switching power converter system 100 or the flying capacitor switching converter 400.

As an example, the number of voltage levels in a flying capacitor switching converter can be determined by the maximum bus voltage (e.g., V_{DC_MAX}) and the voltage rating of the individual switches. In some applications or conditions, the bus voltage V_{DC} can be lower than the maximum bus voltage V_{DC_MAX}. During such applications or conditions, fewer switches can be implemented in series without exceeding the voltage rating of the switches. If the amplitude of the bus voltage V_{DC} is low enough, the flying capacitor switching converter 400 can be operated with fewer voltage levels without losing the ability to return to the normal operating mode, and thus the nominal quantity of voltage levels, when the bus voltage approaches the maximum bus voltage V_{DC_MAX}.

For example, a portion of the switching losses of a given flying capacitor switching converter can be dependent on the quantity of switching stages 402 that are being switched at the appropriate switching frequency. As a result, the flying capacitor switching converter 400 can operate more efficiently at a lesser quantity of switching stages 402, particularly at lower amplitudes of the input voltage V_{DC}. Accordingly, selectively adjusting the quantity of voltage levels of the flying capacitor switching converter 400 can provide for a better low-load operating efficiency of the flying capacitor switching converter 400, such as relative to conventional flying capacitor switching converters having a fixed quantity of voltage levels.

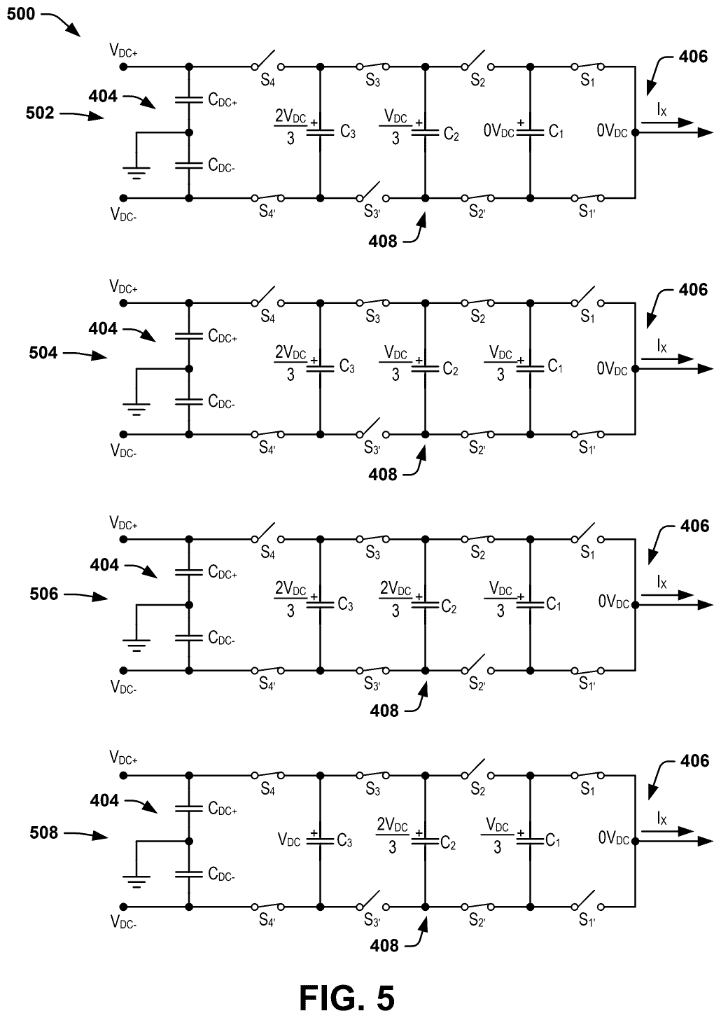

FIG. 5 illustrates an example diagram 500 of different states of the flying capacitor switching converter 400. The diagram 500 includes a first state 502, a second state 504, a third state 506, and a fourth state 508. Each of the states 502, 504, 506, and 508 demonstrates a different manner of concurrently closing the switches of a given one of the switching stages 402. In the example of FIG. 5, the switches S₁ through S₄ and S₁′ through S₄′ are illustrated as mechanical switches for purposes of explanation, but can correspond to the transistor devices as provided in the example of FIG. 4.

The first state 502 demonstrates that the complementary pair of switches S₁ and S₁′ are both activated, while the complementary pairs of switches S₂ and S₂′, switches S₃ and S₃′, and switches S₄ and S₄′ are demonstrated as including only a single activated switch (the specific activated switch being irrelevant to this example). Therefore, during the operating mode of the flying capacitor switching converter 400 in the first state 502, one of each the complementary pairs of switches S₂ and S₂′, switches S₃ and S₃′, and switches S₄ and S₄′ can be activated (e.g., alternately) at the switching frequency. Accordingly, the state 502 demonstrates a short circuit of the output 406 and the nodes 408 across the first flying capacitor C₁. As a result, the nominal amplitudes of the output 406 and the nodes 408 across the first flying capacitor C₁ are equalized, and are demonstrated as zero (0V_{DC}) in the first state 502.

In response to a reduction in the quantity of voltage levels of the flying capacitor switching converter 400 from the nominal amplitude, the nominal amplitudes of the voltage levels are reallocated across the nodes 408 of the flying capacitor switching converter 400. Particularly, in the first state 502, the nominal voltage amplitude across the first flying capacitor C₁ changes from V_{DC}/4 to 0V_{DC} (equal to the output 406), the nominal voltage amplitude across the second flying capacitor C₂ changes from V_{DC}/2 to V_{DC}/3, and the nominal voltage amplitude across the third flying capacitor C₃ changes from 3V_{DC}/4 to 2V_{DC}/3.

The second state 504 demonstrates that the complementary pair of switches S₂ and S₂′ are both activated, while the complementary pairs of switches S₁ and S₁′, switches S₃ and S₃′, and switches S₄ and S₄′ are demonstrated as including only a single activated switch (the specific activated switch being irrelevant to this example). Therefore, during the operating mode of the flying capacitor switching converter 400 in the second state 504, one of each the complementary pairs of switches S₁ and S₁′, switches S₃ and S₃′, and switches S₄ and S₄′ can be activated (e.g., alternately) at the switching frequency. Accordingly, the state 504 demonstrates a short circuit of the nodes 408 across the first flying capacitor C₁ and the second flying capacitor C₂. As a result, the nominal amplitudes of the nodes 408 across the first and second flying capacitors C₁ and C₂ are equalized, and are demonstrated as V_{DC}/3 in the second state 504.

In response to a reduction in the quantity of voltage levels of the flying capacitor switching converter 400 from the nominal amplitude, the nominal voltage amplitude across the first flying capacitor C₁ changes from V_{DC}/4 to V_{DC}/3. The nominal voltage amplitude across the second flying capacitor C₂ changes from V_{DC}/2 to V_{DC}/3 (equal to the first flying capacitor C₁). The nominal voltage amplitude across the third flying capacitor C₃ changes from 3V_{DC}/4 to 2V_{DC}/3.

The third state 506 demonstrates that the complementary pair of switches S₃ and S₃′ are both activated, while the complementary pairs of switches S₁ and S₁′, switches S₂ and S₂′, and switches S₄ and S₄′ are demonstrated as including only a single activated switch (the specific activated switch being irrelevant to this example). Therefore, during the operating mode of the flying capacitor switching converter 400 in the third state 506, one of each the complementary pairs of switches S₁ and S₁′, switches S₂ and S₂′, and switches S₄ and S₄′ can be activated (e.g., alternately) at the switching frequency. Accordingly, the state 506 demonstrates a short circuit of the nodes 408 across the second flying capacitor C₂ and the third flying capacitor C₃. As a result, the nominal amplitudes of the nodes 408 across the second and third flying capacitors C₂ and C₃ are equalized, and are demonstrated as 2V_{DC}/3 in the third state 506.

In response to a reduction in the quantity of voltage levels of the flying capacitor switching converter 400 from the nominal amplitude, the nominal voltage amplitude across the first flying capacitor C₁ changes from V_{DC}/4 to V_{DC}/3. The nominal voltage amplitude across the second flying capacitor C₂ changes from V_{DC}/2 to 2V_{DC}/3 (equal to the third flying capacitor C₃). The nominal voltage amplitude across the third flying capacitor C₃ changes from 3V_{DC}/4 to 2V_{DC}/3.

The fourth state 508 demonstrates that the complementary pair of switches S₄ and S₄′ are both activated, while the complementary pairs of switches S₁ and S₁′, switches S₂ and S₂′, and switches S₃ and S₃′ are demonstrated as including only a single activated switch (the specific activated switch being irrelevant to this example). Therefore, during the operating mode of the flying capacitor switching converter 400 in the fourth state 508, one of each the complementary pairs of switches S₁ and S₁′, switches S₂ and S₂′, and switches S₃ and S₃′ can be activated (e.g., alternately) at the switching frequency. Accordingly, the state 508 demonstrates a short circuit of the input 404 and the nodes 408 across the third flying capacitor C₃. As a result, the nominal amplitudes of the input 404 and the nodes 408 across the third flying capacitor C₃ are equalized, and are demonstrated as 2V_{DC}/3 in the fourth state 508.

In response to a reduction in the quantity of voltage levels of the flying capacitor switching converter 400 from the nominal amplitude, the nominal voltage amplitude across the first flying capacitor C₁ changes from V_{DC}/4 to V_{DC}/3. The nominal voltage amplitude across the second flying capacitor C₂ changes from V_{DC}/2 to 2V_{DC}/3. The nominal voltage amplitude across the third flying capacitor C₃ changes from 3V_{DC}/4 to V_{DC} (equal to the input 404).

In any of the states 502, 504, 506, and 508, deactivation of one of the concurrently activated switches can thus return the flying capacitor switching converter 400 back to a nominal state (e.g., as demonstrated in the example of FIG. 4), and thus back to the normal operating mode at which all of the complementary pairs of switches S₁ and S₁′, switches S₂ and S₂′, switches S₃ and S₃′, and switches S₄ and S₄′ are activated (e.g., alternately) at the switching frequency. The example of FIG. 5 thus demonstrates one example of selectively changing the quantity of voltage levels of a flying capacitor switching converter between a nominal quantity and a quantity lesser than the nominal quantity. The manner of selectively changing the quantity of voltage levels can be extended to any of a variety of topologies of flying capacitor switching converters, and is not limited to four switching stages 402. Additionally, while the example of FIG. 5 demonstrates only a single reduction in quantity of the voltage levels from the nominal quantity, the complementary switches of an additional switching stage 402 can be concurrently activated to further reduce the quantity of voltage levels.

If the switch controller 102 concurrently activates the switches of the switching stage 402 during the normal operating mode, a significantly large current spike would flow through the switches because one of the flying capacitors at one voltage is shorted to another flying capacitor at another voltage (or directly shorted in the example of the first flying capacitor C₁), which can result in damage or failure to the switches of the switching stages and/or the flying capacitors. Therefore, to mitigate such a current spike, the switch controller 102 can be configured to concurrently activate the complementary switches of a given switching stage 402 when the voltage across the respective switches is approximately zero. To achieve the condition in which both switches of a complementary pair have approximately zero voltage across them, the controller can adjust the voltages across the flying capacitors to the amplitudes demonstrated in FIG. 5 prior to activating the pair of switches.

For example, the voltage amplitude of the flying capacitor C₁ can be adjusted to approximately 0V_{DC} before closing both of the switches S₁ and S₁′ in the first state 502.

Similarly, the voltage amplitude of the flying capacitors C₁ and C₂ can be adjusted to approximately V_{DC}/3 before closing both of the switches S₂ and S₂′ in the second state 504.

Similarly, the voltage amplitude of the flying capacitors C₂ and C₃ can be adjusted to approximately 2V_{DC}/3 before closing both of the switches S₃ and S₃′ in the third state 506.

Similarly, the voltage amplitude of the flying capacitor C₃ can be adjusted to approximately V_{DC} before closing both of the switches S₄ and S₄′ in the fourth state 508.

As an example, the switch controller 102 can be configured to monitor the feedback signals FDBK provided from the flying capacitor switching converter 400 to determine the appropriate time to concurrently activate the switches of a given switching stage at approximately zero volts across the respective switches. As an example, the flying capacitor switching converter 400 can be designed to accommodate a capacitor ripple voltage of +/−10% of the nominal voltage amplitude on the flying capacitor C₁. Allowing a capacitor voltage ripple can reduce the size and cost of the flying capacitors. Therefore, the switch controller 102 can implement a voltage-balancing algorithm to set targeted voltage amplitudes of the one or two of the flying capacitors that are to be short-circuited to other nodes to be approximately equal before commanding the concurrent activation of the complementary switches of the respective switching stage 402.

For example, the switch controller 102 can then monitor the feedback voltages V_{FB} at each of the nodes 408 to determine when the respective nodes have approximately the same amplitude. The feedback voltages V_{FB} can be monitored in any of a variety of ways. For example, by monitoring the amplitude of the output current I_{X} and the instantaneous states of the switches, the switch controller 102 can identify the magnitude and direction of the current through each of the flying capacitors, and can thus ascertain the amplitude and timing of the voltage ripple on the flying capacitors. Combined with measurement of the average voltage across the flying capacitors, the relative voltages on the nodes 408 can be identified by the switch controller 102 at any given time. The switch controller 102 can thus command the concurrent activation of the complementary switches of the respective switching stage 402 in response to determining that the voltages at the nodes 408 across the switches are approximately equal.

The switch controller 102 can provide a similar methodology to concurrently activate the switches S₁ and S₁′ to short circuit the first flying capacitor C₁ to the output 406, or to concurrently activate the switches S₄ and S₄′ to short circuit the third flying capacitor C₃ to the input 404. As a first example, based on monitoring the feedback voltage V_{FB} across the first flying capacitor C₁ (e.g., based on amplitude of the output current I_{X} and the states of the switches), the switch controller 102 can identify the time at which the voltage across the first flying capacitor C₁ is approximate zero volts (e.g., at an approximate zero-crossing). Similarly, as a second example, based on monitoring the feedback voltage V_{FB} across the third flying capacitor C₃ (e.g., based on amplitude of the output current I_{X} and the states of the switches), the switch controller 102 can identify the time at which the voltage across the third flying capacitor C₃ is approximately equal to (or closest to) the input voltage V_{DC}.

As described above, the switch controller 102 can be configured to provide the switching signals SW and SW′ at a variable frequency. Because voltage ripple on the flying capacitors C₁ through C₃ can increase approximately linearly as a function of the current I_{X} and the switching period of the switching signals SW and SW′. Therefore, the switch controller 102 can be configured to vary the switching frequency of the switching signals SW and SW′ linearly with the amplitude of the output current, such as within a fundamental period of an AC operating current (e.g., 50 Hz or 60 Hz for AC powerline applications). As a result, at lower amplitudes of the current I_{X}, the flying capacitor switching converter 400 can be operated at lower switching frequencies without increasing the voltage ripple across the flying capacitors C₁ through C4, thereby enabling an improved low-load operating efficiency relative to conventional flying capacitor switching converters having a fixed switching period.

The flying capacitor switching converter 400 can provide the output voltage V_{X} to the associated load via an output filter. As an example, the output filter can be configured as a combination of inductors and capacitors (e.g., an LCL filter). While the voltage ripple on the flying capacitors C₁ through C₃ can increase approximately linearly as a function of the current I_{X} and the switching period of the switching signals SW and SW′, the current ripple in an inductor associated with the output filter can increase linearly with the voltage across an associated power inverter and the switching period of the switching signals SW and SW′. The current ripple in the output filter can thus be excessive in the absence of a very large inductor in the output filter, particularly at low switching frequencies of the switching signals SW and SW′. However, such a very large inductor can be impractically bulky for certain circuit designs in which it is a goal to minimize the size.

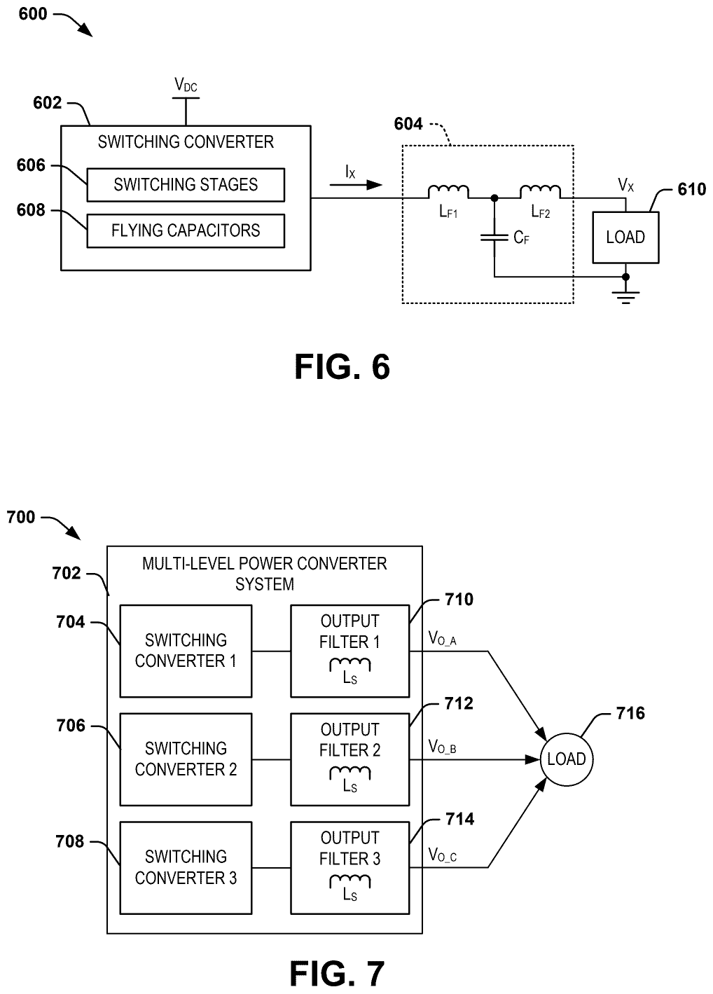

FIG. 6 illustrates another example block diagram of a switching converter system 600. The switching converter system 600 includes a switching converter 602 and an output filter 604. The switching converter system 600 can correspond to one of the switching converters 104 in the example of FIG. 1, and can correspond more specifically to the flying capacitor switching converter 300 in the example of FIG. 3. Similar to as described above, the switching converter system 600 includes a plurality of switching stages 606 that each include a set of switches (e.g., high-frequency switching transistor devices) and a plurality of flying capacitors 608. The switching stages 606 can thus each correspond to one of the switching stages 402 of the flying capacitor switching converter 400, and can therefore include a complementary pair of switches coupled to at least one of the flying capacitors 608.

As an example, the switching stages 606 can be controlled by the switching signals SW and SW′ (not shown in the example of FIG. 6) to provide the respective output voltage V_{X} and a plurality of voltage levels across each of the flying capacitors 608. The output voltage V_{X} is demonstrated as being provided to a load 610 via an output current I_{X} provided through the output filter 604. As an example, the load 610 can correspond to an AC grid for an inverter or other application in which a filter is required to meet harmonic and/or EMI requirements. The output filter 604 includes a first inductor L_{F1} coupled to a second inductor L_{F2} and a capacitor C_{F} to form an LCL filter. The output filter 604 can be configured to reduce current ripple at the switching frequency of the switching signals SW and SW′ and to reduce electro-magnetic interference (EMI) emissions from the switching converter system 600. While the output filter 604 is demonstrated as the LCL filter in the example of FIG. 6, other arrangements of inductive and capacitive filters are similarly possible.

In the example of FIG. 6, at least one of the inductors L_{F1} and L_{F2} can be configured as a saturable inductor. As an example, the first inductor L_{F1} can be configured as a saturable inductor exhibiting a nonlinear behavior of inductance as a function of current. As described above, the switching converter 602 can operate at a variable switching frequency based on a variable frequency of the switching signals SW and SW′, such that the switching converter 602 can operate at a lower switching frequency at lesser amplitudes of the output current I_{X} to mitigate the voltage ripple across the flying capacitors 608. However, as also described above, the current ripple in the inductor L_{F1} and/or the inductor L_{F2} can increase linearly with the voltage across an associated power inverter and the switching period of the switching signals SW and SW′. Therefore, based on the nonlinear behavior of inductance as a function of the amplitude of the output current I_{X}, the inductor L_{F1} and/or the inductor L_{F2} configured as a saturable inductor can mitigate the current ripple through the output filter 604.

For example, the saturable inductor can be configured to saturate in response to an amplitude of the output current I_{X} through the switching converter system 600 being less than approximately 20% of a rated peak current of the switching converter system 600. Accordingly, the variable frequency of the switching converter 602 combined with the saturable inductor(s) in the output filter 604 can balance voltage and current ripple to provide for a more efficient operation of the switching converter system 600.

FIG. 7 illustrates another example block diagram 700 of a multi-level switching power converter system 702. The multi-level switching power converter system 702 includes a first switching converter 704, a second switching converter 706, and a third switching converter 708. As an example, the switching converters 704, 706, and 708 can each correspond to a flying capacitor switching converter (e.g., the flying capacitor switching converter 300 in the example of FIG. 3). The multi-level switching power converter system 702 also includes a first output filter 710, a second output filter 712, and a third output filter 714. Each of the output filters 710, 712, and 714 can be arranged as an inductive and capacitive filter (e.g., an LCL filter) that includes at least one saturable inductor L_{S}.

In the example of FIG. 7, the first switching converter 704 is configured to provide a first output voltage V_{O_A} to a load 716 via the first output filter 710. Similarly, the second switching converter 706 is configured to provide a second output voltage V_{O_B} to the load 716 via the second output filter 712. Similarly, the third switching converter 708 is configured to provide a third output voltage V_{O_C} to the load 716 via the third output filter 714. As an example, the load 716 can correspond to a utility grid connection, as described above in the example of FIG. 6, such that output voltages V_{O_A}, V_{O_B}, and V_{O_C} are provided at different phases.

As described above, the switching converters 704, 706, and 708 can be configured as flying capacitor switching converters, such that the switching converters 704, 706, and 708 can be operated at a variable switching frequency as described above. Thus, the switching converters 704, 706, and 708 can operate at a low switching frequency based on a low-load condition of the load 716 to mitigate voltage ripple in the associated flying capacitors. Additionally, by including the saturable inductor(s) L_{S} in each of the respective output filters 710, 712, and 714, current ripple through the output filters 710, 712, and 714 can be mitigated at low-frequency switching of the switching converters 704, 706, 708. Accordingly, the multi-level switching power converter system 702 can provide efficient control of the load (e.g., motor) 716.

While the example of FIG. 7 is described as the switching converters 704, 706, and 708 being configured as flying capacitor switching converters, other types of switching converters can be implemented instead. As an example, the switching converters 704, 706, and 708 can be configured as cascaded H-bridge switching converters, or as TAB switching converters, as described below.

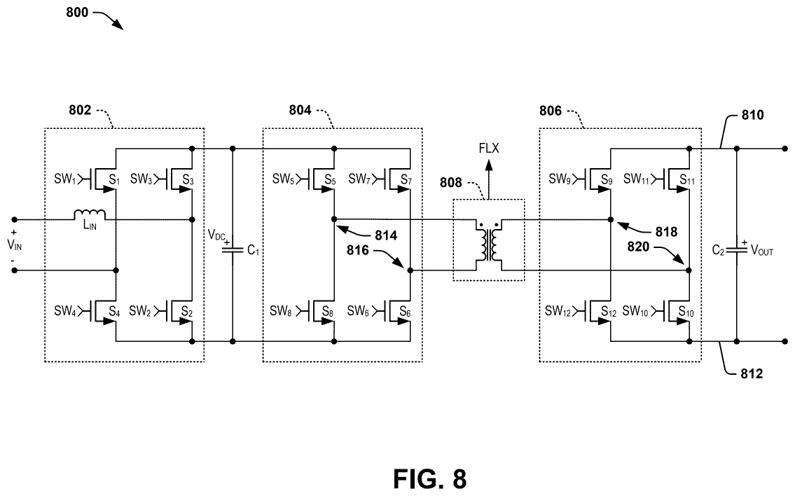

FIG. 8 illustrates another example circuit diagram of a switching converter 800. The switching converter 800 is demonstrated in the example of FIG. 8 as a TAB switching converter, and can correspond to one or more of the switching converters 104 in the example of FIG. 1 or the switching converter 200 in the example of FIG. 2. Therefore, reference is to be made to the examples of FIGS. 1 and 2 in the following example of FIG. 8.

The TAB switching converter 800 includes a first switching stage 802, a second switching stage 804, a third switching stage 806, and a transformer 808. Each of the switching stages 802, 804, 806 are demonstrated as an H-bridge that includes four switches, such as high-speed transistor devices (e.g., GaN or SiC transistor devices). While the switches are described herein as high-speed transistor devices, other types of switch topologies can be implemented for each switch, as well (e.g., parallel transistor sets).

The first switching stage 802 includes a first switch S₁ that is controlled by a first switching signal SW₁, a second switch S₂ that is controlled by a second switching signal SW₂, a third switch S₃ that is controlled by a third switching signal SW₃, and a fourth switch S₄ that is controlled by a fourth switching signal SW₄. The second switching stage 804 includes a fifth switch S₅ that is controlled by a fifth switching signal SW₅, a sixth switch S₆ that is controlled by a sixth switching signal SW₆, a seventh switch S₇ that is controlled by a seventh switching signal SW₇, and an eighth switch S₈ that is controlled by an eighth switching signal SW₈. The third switching stage 806 includes a ninth switch S₉ that is controlled by a ninth switching signal SW₉, a tenth switch S₁₀ that is controlled by a tenth switching signal SW₁₀, an eleventh switch S₁₁ that is controlled by an eleventh switching signal SW₁₁, and a twelfth switch S₁₂ that is controlled by a twelfth switching signal SW₁₂. The switching signals SW₁ through SW₁₂ can correspond to the switching signals SW₁ through SW_{M} in the example of FIG. 2, and can thus be provided from the switch controller 102 at a variable frequency and/or variable phase.

In the example of FIG. 8, the TAB switching converter 800 is configured to convert an AC input voltage V_{IN} to a DC output voltage V_{OUT}. The AC input voltage V_{IN} is provided to the first switching stage 802 via an input inductor L_{IN} to provide a DC input voltage V_{DC} across a capacitor C₁. As an example, the AC input voltage V_{IN} can be converted to an AC current through the input inductor L_{IN} and can be rectified by the first switching stage 802 to provide a unipolar current onto the capacitor C₁ which peaks twice per AC cycle and is zero twice per AC cycle. For example, the first switching stage 802 can be configured to provide the DC input voltage V_{DC} from the AC input voltage V_{IN} via the input inductor L_{IN} at an amplitude ratio greater than one.

The second switching stage 804 is coupled to a first winding (e.g., primary winding) of the transformer 808 to provide the DC input voltage V_{DC} to the first winding of the transformer 808. The third switching stage 806 is coupled to a second winding (e.g., secondary winding) of the transformer 808 to generate the DC output voltage V_{OUT} across an output capacitor C₂ arranged between a first output rail 810 and a second output rail 812 in response to a current induced at the second winding of the transformer 808 in response to the DC input voltage V_{DC}. As described in greater detail herein, the transformer 808 can be configured to generate a flux signal FLX that can correspond to a magnetic flux through the magnetic core of the transformer 808. The flux signal FLX can correspond to one of the feedback signals FDBK that is provided to the switch controller 102.

The TAB switching converter 800 is demonstrated in the example of FIG. 8 and described herein as unidirectional. However, it is to be noted that the description of the TAB switching converter 800 as converting an AC input voltage via the primary winding to provide a DC voltage via a secondary winding is one example implementation regarding the orientation of the TAB switching converter 800. As another example, the TAB switching converter 800 can operate bidirectionally, such that the input stage/primary and output stage/secondary could be reversed. For example, the TAB switching converter 800 could be configured to generate an AC output voltage in response to a DC input voltage. As another example, an additional switching stage (e.g., H-bridge) could be added to the third switching stage 806 to generate an AC output voltage in response to the AC input voltage. As yet another example, the first switching stage 802 can be omitted to provide a dual-active bridge (DAB) switching converter that converts a DC input voltage to a DC output voltage. Many of the operational principles described below can apply equally to a DAB switching converter.

As yet another example, the TAB switching converter 800 or similar DAB switching converter can be configured using a planar transformer module that includes printed circuit boards (PCBs) on which the coils of the transformer 808 are printed. For example, the first (primary) winding of the transformer 808 can be printed on a first set of PCBs and the second (secondary) winding of the transformer 808 can be printed on a second set of PCBs. As an example, the first and second switching stages 802 and 804 can thus be fabricated on the first set of PCBs and the third switching stage 806 can be fabricated on the second set of PCBs. An example arrangement of a planar/solid-state transformer is described in U.S. Ser. No. 18/585,173, filed Feb. 23, 2023 (Attorney Docket No. MPWR-033246 US PRI), which is incorporated herein by reference in its entirety. Accordingly, a DAB or TAB switching converter (e.g., the TAB switching converter 800) can be arranged in a variety of ways as described herein.

The second switching stage 804 includes a first switching node 814 arranged between the fifth and eighth switches S₅ and S₈ and a second switching node 816 arranged between the sixth and seventh switches S₆ and S₇. Similarly, the third switching stage 806 includes a third switching node 818 arranged between the ninth and twelfth switches S₉ and S₁₂ and a fourth switching node 820 arranged between the tenth and eleventh switches S₁₀ and S₁₁. In the example is of FIG. 8, the first and second switching nodes 814 and 816 are demonstrated as directly coupled to the first winding of the transformer 808. Similarly, the third and fourth switching nodes 818 and 820 are demonstrated as directly coupled to the second winding of the transformer 808. As described herein, the term “directly coupled” refers to a short-circuited electrical connection between the devices, and thus without any interposing circuit devices (such as a blocking capacitor).

As an example, the TAB switching converter 800 can be implemented in a high power application, such as having a power rating of tens of kW or more. For example, the TAB switching converter 800 can operate with an AC input voltage amplitude of between approximately 500 VAC and 2 kVAC, and a DC input/output voltage amplitude of at least 750 VDC. The windings of the transformer 808 can thus be designed to provide sufficient isolation for any of a variety of high-power applications, such as to provide at least 50 kV of isolation between the first and second windings. For example, for the TAB switching converter 800 arranged as a planar transformer, the transformer 808 can include a ceramic electrical insulator to electrically isolate the first winding of the transformer 808 and the second switching stage 804 from the second winding of the transformer 808 and the third switching stage 806.

For a conventional power converter system operating at such high power applications, such as using a DAB switching converter, an additional external DC blocking capacitor is provided between the transformer winding(s) and the switching stage(s) to eliminate the possibility of saturating the transformer. Such an external DC blocking capacitor can be very physically large and expensive in very high power (high current) applications.

As described above, the switching signals SW₁ through SW₁₂ can be provided from the switch controller 102 at a variable frequency and/or variable phase to control the power flow through the TAB switching converter 800 via the high speed switching capability and control resolution of the switches S₁ through S₁₂ (e.g., via a switching time of less than 20 nanoseconds). As an example, the switch controller 102 can provide the switching signals SW₁ and SW₁₂ in a dual phase-shift scheme. As an example, the dual phase-shift scheme can include phase-shifting the set of switching signals SW₅ through SW₈ of the second switching stage 804 relative to the switching signals SW₉ through SW₁₂ of the third switching stage 806 to control power flow through the transformer 808.

As another example, the dual phase-shift scheme can include phase-shifting the switching signals in the switching stages 804 and/or 806. For example, the switching signals SW₆ and SW₇ can be phase-shifted relative to the switching signals SW₅ and SW₈ of the second switching stage 804, or the switching signals SW₁₀ and SW₁₁ can be phase-shifted relative to the switching signals SW₉ and SW₁₂ of the third switching stage 806. As described in greater detail herein, the phase-shift of the switching signals SW₁₀ and SW₁₁ relative to the switching signals SW₉ and SW₁₂ of the third switching stage 806 can provide for more than two switching states of the third switching stage 806.

As an example, by phase-shifting a pair of the switches in a given switching stage 804 and/or 806 relative to the other pair in the same one of the switching stages 804 and/or 806 saturation of the transformer 808 at low average currents can be mitigated when operating at lower frequency. For example, the ramp rate of the current through the transformer 808 can depend on the effective voltage across the leakage inductance of the transformer 808, which can depend on the states of the switches in the switching stages 802, 804, and/or 806 and the voltages across the capacitors C₁ and C₂. Because the voltages across the capacitors C₁ and C₂ can remain the same at all currents, reducing the switching frequency at low current can result in the dwell time in each switching state to be longer, resulting in a larger swing in the current before the next switching state. If the current ripple amplitude increases to too large an amplitude, the transformer 808 can saturate at the peak amplitudes. However, implementing the dual phase-shift scheme can allow the dwell time in the high-voltage states to be reduced at a given frequency so that as the switching period can increase at lower switching frequency to maintain a short enough dwell time to not saturate the transformer 808.

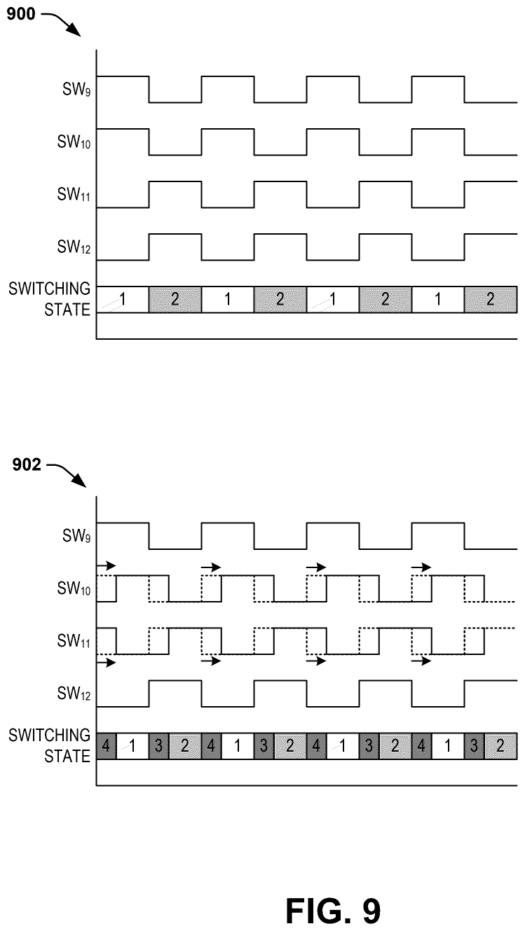

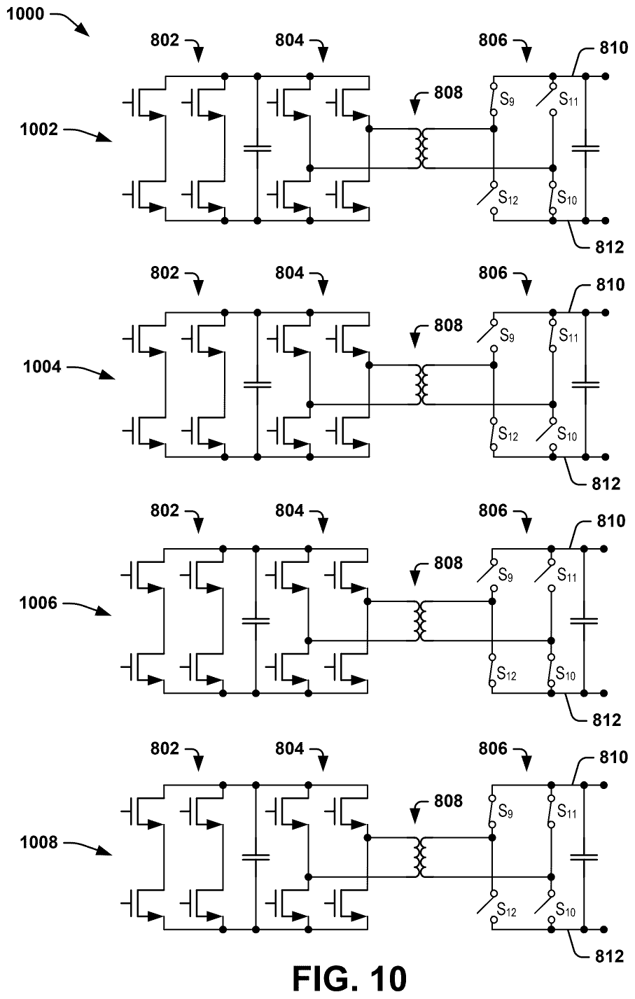

FIG. 9 illustrates example timing diagrams 900 and 902. The timing diagrams 900 and 902 demonstrate the switching signals SW₉ through SW₁₂ plotted as a function of time. With reference to FIG. 9, FIG. 10 illustrates an example diagram 1000 of different switching states of the TAB switching converter 800. FIG. 10 demonstrates the TAB switching converter 800 in a more simplistic manner for ease of explanation, in which the switches S₉ through S₁₂ are illustrated as mechanical switches, but can correspond to the transistor devices as provided in the example of FIG. 8. Therefore, the timing diagrams 900 and 902, as well as the diagram 1000, demonstrate separate ways of controlling the switching of the third switching stage 806 in the example of FIG. 8.

In the example of FIG. 9, the timing diagram 900 demonstrates a nominal switching scheme of third switching stage 806. In the timing diagram 900, the switching signals SW₉ and SW₁₀ are logically asserted to activate the respective switches S₉ and S₁₀ concurrently in a first switching state (“1”). At the same time during the first switching state, the switching signals SW₁₁ and SW₁₂ are logically de-asserted to deactivate the respective switches S₁₁ and S₁₂ concurrently. Therefore, in the first switching state, the output voltage V_{OUT} is provided based on the concurrently activated switches S₉ and S₁₀ between a first output rail 810 and a second output rail 812 across the output capacitor C₂. The first switching state is demonstrated at 1002 in the example of FIG. 10, in which the voltage applied to the secondary winding of the transformer is +V_{OUT}.

Additionally, the switching signals SW₁₁ and SW₁₂ are logically asserted to activate the respective switches S₁₁ and S₁₂ concurrently in a second switching state (“2”). At the same time during the second switching state, the switching signals SW₉ and SW₁₀ are logically de-asserted to deactivate the respective switches S₉ and S₁₀ concurrently. Therefore, in the second switching state, the output voltage V_{OUT} is provided based on the concurrently activated switches S₁₁ and S₁₂ across the output capacitor C₂ between the first and second output rails 810 and 812. The second switching state is demonstrated at 1004 in the example of FIG. 10, in which the voltage applied to the secondary winding of the transformer is −V_{OUT}.

The second timing diagram 902 demonstrates an adjusted switching scheme of third switching stage 806 resulting from a phase-shift of the switching signals SW₁₀ and SW₁₁ (indicated by the arrows and phantom lines in FIG. 10) relative to the switching signals SW₉ and SW₁₂ based on the dual phase-shift scheme. In the timing diagram 902, the switching signals SW₉ and SW₁₀ are logically asserted to activate the respective switches S₉ and S₁₀ concurrently in a first switching state (“1”, and at 1002 in the example of FIG. 10). At the same time during the first switching state, the switching signals SW₁₁ and SW₁₂ are logically de-asserted to deactivate the respective switches S₁₁ and S₁₂ concurrently. Therefore, in the first switching state, the output voltage V_{OUT} is provided based on the concurrently activated switches S₉ and S₁₀ across the output capacitor C_{2.}

Additionally, the switching signals SW₁₁ and SW₁₂ are logically asserted to activate the respective switches S₁₁ and S₁₂ concurrently in a second switching state (“2”, and at 1002 in the example of FIG. 10). At the same time during the second switching state, the switching signals SW₉ and SW₁₀ are logically de-asserted to deactivate the respective switches S₉ and S₁₀ concurrently. Therefore, in the second switching state, the output voltage V_{OUT} is provided based on the concurrently activated switches S₁₁ and S₁₂ across the output capacitor C₂.

In addition, the second timing diagram 902 includes a third switching state (“3”) between the first and second switching states (in time order) that is provided based on the phase-shift of the switching signals SW₁₀ and SW₁₁ relative to the switching signals SW₉ and SW₁₂. In the third switching state, the switching signals SW₁₀ and SW₁₂ are logically asserted to activate the respective switches S₁₀ and S₁₂. At the same time during the third switching state, the switching signals SW₉ and SW₁₁ are logically de-asserted to deactivate the respective switches S₉ and S₁₁ concurrently. Therefore, in the third switching state, the concurrently activated switches S₁₀ and S₁₂ provide a short-circuit of the second winding of the transformer 808 to the second output rail 812. The third switching state is demonstrated at 1006 in the example of FIG. 10, in which the voltage applied to the secondary winding of the transformer is 0 volts.

Furthermore, the second timing diagram 902 includes a fourth switching state (“4”) between the second and first switching states (in time order) that is provided based on the phase-shift of the switching signals SW₁₀ and SW₁₁ relative to the switching signals SW₉ and SW₁₂. In the fourth switching state, the switching signals SW₉ and SW₁₁ are logically asserted to activate the respective switches S₉ and S₁₁. At the same time during the fourth switching state, the switching signals SW₁₀ and SW₁₂ are logically de-asserted to deactivate the respective switches S₁₀ and S₁₂ concurrently. Therefore, in the fourth switching state, the concurrently activated switches S₉ and S₁₁ provide a short-circuit of the second winding of the transformer 808 to the first output rail 810. The fourth switching state is demonstrated at 1008 in the example of FIG. 10, in which the voltage applied to the secondary winding of the transformer is also 0 volts.

As described above, phase-shifting the switching signals SW₁₀ and SW₁₁ relative to the switching signals SW₉ and SW₁₂ of the third switching stage 806 can control reactive power, peak current, and/or magnetizing current of the transformer 808 independently of the power flow through the transformer 808. For example, in response to a decrease in the switching frequency of the switching signals SW₁ through SW₁₂, phase-shifting the switching signals SW₁₀ and SW₁₁ relative to the switching signals SW₉ and SW₁₂ can reduce the volt-seconds applied to the magnetic core of the transformer 808, which can prevent the magnetic core from saturating.

In addition, the dual phase-shift scheme can provide a power flow through the second and third switching stages 804 and 806 that is sinusoidal, which can result in instances of low power operation even at high average power. Furthermore, reducing the switching frequency of the switching signals SW₁ through SW₁₂ can reduce the switching losses in the switches S₁ through S₁₂, which can provide for a significant portion of total losses at low power operation of the TAB switching converter 800. Because the losses per switching period can be fixed at low power (e.g., determined by the operating voltage of the TAB switching converter 800), fewer switching transients per unit time can result in lower losses. Accordingly, reducing the switching frequency of the switches S₁ through S₁₂ can be possible at low average power and at the period of low-power operation that occurs twice per line frequency cycle.

The dual phase-shift scheme of the TAB switching converter 800 can thus control the magnetizing current in the magnetic core of the transformer 808, and thus the magnetic resonance of the transformer 808. By having the capability to control the magnetic resonance of the transformer 808 via the switching signals SW₁ through SW₁₂, the TAB switching converter 800 can be designed without a blocking capacitor coupled to the transformer 808. The first and second switching nodes 814 and 816 can thus be directly coupled to the first winding of the transformer 808, and the third and fourth switching nodes 818 and 820 can thus be directly coupled to the second winding of the transformer 808. The omission of the blocking capacitor coupled to the transformer 808 can thus provide for a significantly more compact circuit design for high power applications of the TAB switching converter 800, such as in a planar transformer configuration.

The variable frequency and/or variable phase-shift control of the switching signals SW₁ through SW₁₂ can be provided based on closed-loop control of the TAB switching converter 800. As described above, the transformer 808 can generate a flux signal FLX corresponding to a magnetic flux through the magnetic core of the transformer 808 as feedback (e.g., one of the feedback signals FDBK) to the switch controller 102.

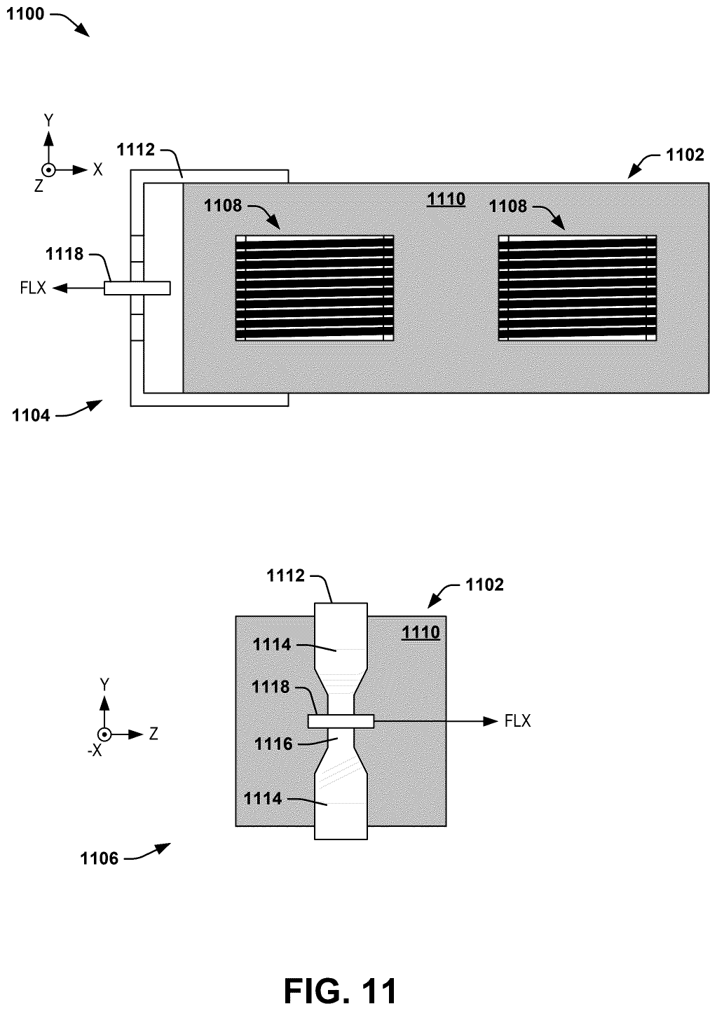

FIG. 11 illustrates an example diagram 1100 of a transformer 1102. The transformer 1102 is demonstrated in a first view 1104 along a-Z axis and in a second view 1106 along an X-axis. The transformer 1102 can correspond to the transformer 808 in the example of FIG. 8. The transformer 1102 is demonstrated in the example of FIG. 11 simplistically for ease of explanation, and is not limited to the representation provided herein.

In the example of FIG. 11, the transformer 1102 includes windings 1108 and a magnetic core 1110. The magnetic core 1110 can be formed from a first material having a first magnetic permeability. For example, the magnetic core 1110 can be formed from any of a variety of ferrite materials. In addition, the transformer 1102 includes a saturable magnetic element 1112 that is coupled to the magnetic core 1110. The saturable magnetic element 1112 can be formed from a second material having a second magnetic permeability that is higher than the magnetic permeability of the first material from which the magnetic core 1110 is formed. For example, the saturable magnetic element 1112 can be formed from any of a variety of nickel-based alloys.

The saturable magnetic element 1112 is demonstrated as having first portions 1114 and a second portion 1116 extending between and interconnecting the first portions 1114. The first portions 1114 are coupled respectively to the top and bottom of the magnetic core 1110. The second portion 1116 is demonstrated as being thinner in at least one dimension (e.g., the Z-axis in the example of FIG. 11) relative to the first portions 1114. Therefore, the second portion 1116 has a cross-sectional area that is less than a cross-sectional area of the first portions 1114.

In the example of FIG. 11, a sense coil 1118 is demonstrated as surrounding the second portion 1116. The sense coil 1118 can be configured as a passive coil in which a current is induced in response to a magnetic flux provided through the saturable magnetic element 1112. The induced current thus corresponds to the flux signal FLX that can be provided as the feedback signal FDBK to the switch controller 102. As described herein, the term “passive” with respect to the sense coil 1118 or that the flux signal FLX is “passively generated” refers to the sense coil 1118 providing the flux signal FLX in response to only the magnetic flux through the saturable magnetic element 1112, and thus without any signal or current being provided to the sense coil 1118. The saturable magnetic element 1112 is demonstrated as coupled to the magnetic core 1110 in a manner that allows the saturable magnetic element 1112 to divert a portion of the magnetic flux through the magnetic core 1110 through the saturable magnetic element 1112 instead.

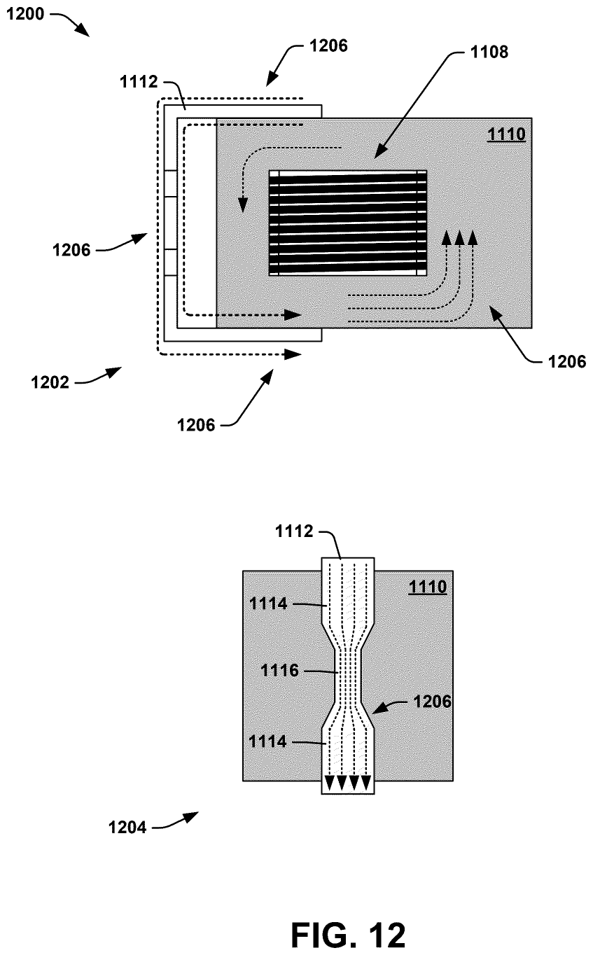

FIG. 12 illustrates another example diagram 1200 of the transformer 1102. The transformer 1102 is demonstrated in a first view 1202 corresponding to the first view 1104 in the example of FIG. 11, and in a second view 1204 corresponding to the second view 1106 in the example of FIG. 11. In the example of FIG. 12, the sense coil 1118 is omitted, and only a portion of the transformer 1102 is demonstrated in the first view 1202 for ease of explanation.

The magnetic flux through the magnetic core 1110 is demonstrated at 1206 as dotted lines flowing around the magnetic core 1110 and through the saturable magnetic element 1112. The higher magnetic permeability of the saturable magnetic element 1112 can allow a fractional portion of the magnetic flux 1206 to flow through the saturable magnetic element 1112 instead of through the magnetic core 1110. Additionally, the higher magnetic permeability and geometry of the saturable magnetic element 1112 allows saturation of the saturable magnetic element 1112 before saturation of the magnetic core 1110. For example, the saturable magnetic element 1112 can be configured to saturate at a magnetizing field magnitude that is less than half the magnetizing field magnitude of the magnetic core 1110.

As described above, the sense coil 1118 is configured to generate the flux signal FLX in response to the magnetic flux 1206 through the saturable magnetic element 1112. Therefore, the flux signal FLX can provide a predictive indication of saturation of the magnetic core 1110. Because the saturable magnetic element 1112 has a narrower cross-section through the second portion 1116 around which the sense coil 1118 is provided, the magnetic flux 1206 can be more concentrated through the second portion 1116 to provide for greater sensitivity of the sensing of the magnetic flux 1206.

The flux signal FLX can thus be provided to the switch controller 102 (e.g., as one of the feedback signals FDBK) to provide control of the variable frequency and/or the variable phase of the switching signals SW₁ through SW₁₂ to the TAB switching converter 800. For example, the switch controller 102 can adjust the variable frequency and/or the variable phase (e.g. the dual phase-shift scheme described above) to actively prevent saturation of the magnetic core 1110. Accordingly, the variable frequency and dual phase-shift control of the switching signals SW₁ through SW₁₂ in response to a measurement of magnetic flux through the transformer 1102 can allow high-power operation of the TAB switching converter 800 without a large blocking capacitor. While the above discussion is provided with reference to the TAB switching converter 800, similar principles can be provided to control of a DAB switching converter, as well.

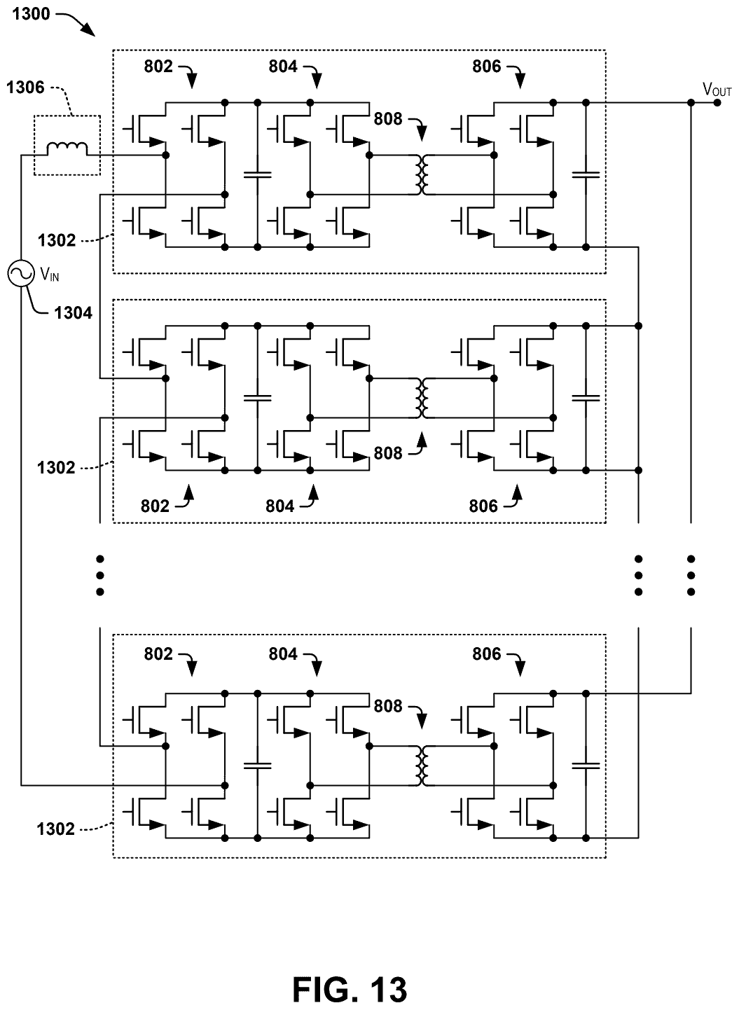

FIG. 13 illustrates an example circuit diagram of a multi-level switching power converter system 1300. The multi-level switching power converter system 1300 can correspond to a portion of the multi-level switching power converter system 100 in the example of FIG. 1. The multi-level switching power converter system 1300 includes a plurality of TAB switching converters 1302, each of which corresponding by example to the TAB switching converter 800. The multi-level switching power converter system 1300 can thus correspond to a high-power voltage converter circuit to generate an output voltage V_{OUT} (e.g., a DC output voltage) in response to an AC input voltage V_{IN}. As an example the multi-level switching power converter system 1300 can provide voltage conversion for an EV charging station.

As an example, the TAB switching converters 1302 can collectively convert a medium amplitude AC voltage V_{IN}, such as at least 5 kVAC (e.g., 7.5 kVAC), provided from an AC voltage source 1304 a high amplitude DC voltage, such as at least 750 VDC (e.g., 1000 VDC). Each of the TAB switching converters 1302 is demonstrated in the example of FIG. 13 as including three switching stages (e.g., the switching stages 802, 804, and 806) and a transformer (e.g., the transformer 808), similar to as described above for the TAB switching converter 800 in the example of FIG. 8. As an example, each of the TAB switching converters 800 can be fabricated as TAB modules that include a planar/solid-state transformer.

In the example of FIG. 13, the inputs of each of the TAB switching converters 1302 are connected in series (e.g., via first switching stages 802) and each of the outputs of the TAB switching converters 1302 are connected in parallel (e.g., via third switching stages 806). As a result, the multi-level switching power converter system 1300 exhibits a series-in parallel-out architecture. Therefore, the primary windings of the transformer 808 are arranged in series and the secondary windings of the transformer are arranged in parallel to provide a large voltage step-down, while using an approximately 1:1 turns ratio of the transformers. The turns ratios can alternatively be something other than 1:1, such as between approximately 0.5:1 and 2:1. This general topology allows for isolated voltage conversion without the use of large, e.g., 50 or 60 Hz, transformers. A higher transformer frequency allows for the use of smaller transformers, such as a planar transformer. Similar to as described above, while the term “primary” refers to the AC input voltage side and the term “secondary” refers to the DC output voltage side, the configuration of the multi-level switching power converter system 1300 can operate bidirectionally, such that the primary and secondary could be reversed in practice.

Similar to as described above, switching signals SW₁ through SW₁₂ can be provided to each of the TAB switching converters 1302 at a variable frequency and/or variable phase. Therefore, the TAB switching converters 1302 can operate at lower switching frequency at lower currents, and can operate with the dual phase-shift scheme described above. As an example, the switch controller 102 can provide high-frequency switching signals to each of the TAB switching converters 1302 to provide high-speed switching of the switches therein, respectively.

As an example, each of the TAB switching converters 1302 can include communication logic that is configured to convert optical signals to electric signals to provide the high-speed control of the switches S₁ through S₁₂ in each of the TAB switching converters 1302. Alternatively, an aggregate communication logic circuit can be provided for all of the TAB switching converters 1302 to provide isolated switching signals between each of the first and second switching stages 802 and 804 relative to the third switching stage 806 for each respective one of the TAB switching converters 1302. For example, the switch controller 102 can be configured to provide the optical signals that are converted to electric signals.

In addition, in the example of FIG. 13, the multi-level switching power converter system 1300 includes an inductor 1306 in series with the series-connected AC inputs of the TAB switching converters 1302. Therefore, the front end of the multi-level switching power converter system 1300 can act as an active boost rectifier providing the DC voltage on the capacitors (e.g., the input capacitors C₁) between the first and second switching stages 802 and 804 of each of the TAB switching converters 1302. As an example, the inductor 1306 can be configured as a saturable inductor.

While the single inductor 1306 is demonstrated in the example of FIG. 13 in series with the series-connected inputs of the TAB switching converters 1302, an individual inductor can instead be included in the first switching stage 802 of each of the TAB switching converters 1302, such as to provide for a more modular construction of the multi-level switching power converter system 1300. The combination of the AC-DC TAB switching converters 1302 having the inputs connected in series through the primary winding of each of the transformers 808 provides for a multi-level converter input stage which allows multiple lower voltage transistors to be used as the switches of the switching stages 802, 804, and 806 to accommodate a high voltage input from the AC voltage source 1304.

What have been described above are example embodiments. It is, of course, not possible to describe every conceivable combination of components or methodologies for purposes of describing the embodiments, but one of ordinary skill in the art will recognize that many further combinations and permutations of the embodiments are possible. Accordingly, the embodiments are intended to embrace all such alterations, modifications, and variations that fall within the scope of this application, including the appended claims. Additionally, where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

What is claimed is:

1. A multi-level switching power converter system comprising:
a multi-level switching converter arranged as a tri-active bridge (TAB) switching converter, the TAB switching converter comprising:
a transformer comprising a first winding and a second winding;
a first switching stage comprising a first set of switches arranged as a first H-bridge and controlled by a first set of switching signals to convert between an AC voltage and a first DC voltage;
a second switching stage comprising a second set of switches arranged as a second H-bridge and controlled by a second set of switching signals, the second switching stage comprising a first switching node between a first pair of the second set of switches and a second switching node between a second pair of the second set of switches, the first and second switching nodes being directly coupled to the first winding to one of provide or receive a first voltage associated with the first winding in response to one of the first DC voltage and a second DC voltage; and
a third switching stage comprising a third set of switches arranged as a third H-bridge and controlled by a third set of switching signals, the third switching stage comprising a third switching node between a first pair of the third set of switches and a fourth switching node between a second pair of the third set of switches, the third and fourth switching nodes being directly coupled to the second winding to one of provide or receive a second voltage associated with the second winding in response to the other of the first and second DC voltages; and
a switch controller configured to generate the first, second, and third sets of switching signals, to provide at least one of the first, second, and third sets of switching signals at a variable frequency that varies as a function of a power metric associated with a frequency of the AC voltage, to provide a variable phase shift between the second and third sets of switching signals, and to provide a variable phase shift between the respective switching signals that control one switch in each of the first and second pairs of at least one of the second and third sets of switches relative to another one switch in each of the first and second pairs of the respective at least one of the second and third sets of switches.

2. The system of claim 1, wherein the transformer is arranged as a planar transformer comprising the first winding, the second winding, and a magnetic core, wherein the first winding is formed as metallic traces on at least one first printed circuit board (PCB) and the second winding is formed as metallic traces on at least one second PCB, the magnetic core being formed around at least a portion of the first and second PCBs.

3. The system of claim 2, wherein the first and second sets of switches are each formed on at least one of the first PCBs to form the respective first and second switching stages, wherein the third set of switches is formed on at least one of the second PCBs to form the third switching stage.

4. The system of claim 2, wherein the planar transformer comprises at least one liquid cooling tube provided proximal to at least one of the first and second windings.

5. The system of claim 2, further comprising at least one ceramic electrical insulator configured to electrically isolate the first winding and the second set of switches from the second winding and the third set of switches.

6. The system of claim 1, wherein the switch controller is configured to vary at least one of the variable frequency and the variable phase shift of the second and third sets of switching signals in response to a feedback signal associated with the transformer.

7. The system of claim 1, further comprising a saturable inductor coupled in series with the first switching stage.

8. The system of claim 1, wherein each of the first and second DC voltages is at least 750 VDC, wherein the AC voltage is between approximately 500 VAC and 2 kVAC.

9. The system of claim 1, further comprising at least one fiber optic link to transfer logic signals between the switch controller and at least one of the first, second, and third switching stages.

10. The system of claim 1, wherein at least one of the first, second, and third sets of switches are arranged as metal oxide semiconductor field effect transistor (MOSFET) devices.

11. The system of claim 1, wherein at least one of the first, second, and third sets of switches are arranged as silicon carbide (SiC) transistor devices.

12. The system of claim 1, wherein at least one of the first, second, and third sets of switches are arranged as transistor devices comprising:
a heat spreader comprising a base and a plurality of legs that are adapted to be coupled to a mounting surface on which the transistor device is provided;
an interposer that is adapted to be coupled to the mounting surface; and
a transistor bare die comprising a gate terminal, a source terminal, and a drain terminal.

13. A voltage converter circuit comprising a plurality of the TAB switching converter of claim 1, the voltage converter circuit being configured to convert between the AC voltage and the first DC voltage at an amplitude ratio greater than one.

14. A transformer assembly comprising:
a transformer comprising a primary winding, a secondary winding, and a magnetic core formed from a first material;
a magnetic element coupled to the magnetic core and being formed from a second material different from the first material of the magnetic core, the magnetic element being configured to divert a portion of a magnetic flux from the magnetic core of the transformer; and
a sense coil magnetically coupled to the magnetic element, the sense coil being configured to provide a feedback signal that is indicative of saturation of the magnetic core of the transformer.

15. The transformer assembly of claim 14, wherein the second material has a higher magnetic permeability than the first material.

16. The transformer assembly of claim 15, wherein the first material is a ferrite material and wherein the second material is a nickel-based alloy material.

17. The transformer assembly of claim 14, wherein the magnetic element is configured to saturate at a first magnetizing field magnitude and the magnetic core is configured to saturate at a second magnetizing field magnitude, the first magnetizing field magnitude being less than half the second magnetizing field magnitude.

18. The transformer assembly of claim 14, wherein the magnetic element comprises a first portion and a second portion, wherein the second portion has a cross-sectional area through which the portion of the magnetic flux is provided that is less than a cross-sectional area of the first portion, wherein the sense coil surrounds the second portion.

19. The transformer assembly of claim 14, wherein the sense coil is arranged to surround a portion of the magnetic element through which the portion of the magnetic flux is provided, wherein the sense coil is configured to provide the feedback signal in response to a passively generated magnetic field through the sense coil based on the portion of the magnetic flux provided through the magnetic element.

20. A tri-active bridge (TAB) switching converter comprising the transformer assembly of claim 14.
